(19) United States
(12) Patent Application Publication
(10) Pub. No.: US 2013/0181243 A1
(43) Pub. Date: Jul. 18, 2013

(54) Solid State Lighting Device

(71) Applicant: Bor-Jen WU, New Taipei City (TW)

(72) Inventor: Bor-Jen WU, New Taipei City (TW)

(73) Assignee: NAN YA PHOTONICS INC., New Taipei City (TW)

(21) Appl. No.: 13/462,537

(22) Filed: May 2, 2012

(30) Foreign Application Priority Data
Jan. 17, 2012 (TW) 101101724

(51) Int. Cl. H01L 33/50

(52) U.S. Cl. 257/98; 257/E33.061

(57) ABSTRACT

A solid state lighting device, including: a housing, which has a reflective cup inside; a solid state light source, placed inside the housing; a transparent adhesive material, used to seal the solid state light source in the housing; and a multi-layer fluorescent structure, placed on the transparent adhesive material and having a fluorescent layer or a phosphor layer sandwiched by two transparent adhesive layers, so as to absorb light beams from the solid state light source and then emit light of longer wavelengths.

### BACKGROUND OF THE INVENTION

1. Field of the Invention

The present invention relates to a solid state lighting device, especially to a package structure for an LED lighting device.

2. Description of the Related Art

After Edison invented the incandescent light bulb, our life style has changed a lot, and the research for improving lighting apparatuses has kept going ever since. For the present, solid state lighting devices have absorbed the most resources for research and development among the lighting apparatuses due to many advantages they possess. For example, solid state lighting devices have better durability against collision than traditional light sources, which use glass for lampshade and therefore require precaution in transportation and operation.

Among solid state lighting devices, LED (light emitting diode) is most popular.

As the light wavelength of an LED is generally in a narrow range, therefore, only one single light color can be provided by an LED if a light mixing measure is not taken. To provide a white light source, performing a light mixing effect on LED light by utilizing a fluorescent powder is an important measure in solid state lighting. For the present, most white light LEDs use yellow fluorescent powder and blue light LEDs to perform light mixing. Other ways can be using green fluorescent powder and red fluorescent powder to go with blue light LEDs; or using fluorescent powder of three primary colors to go with ultraviolet LEDs.

In a general manufacturing process, a fluorescent powder is first mixed with a transparent adhesive material and then fixed on an LED by a fixing process. The fixing process includes using a conformal structure of an LED, or injecting the mixed transparent adhesive material into a package housing.

However, there are some problems in the general manufacturing process. First, there will be a uniform issue in a light mixing process with a fluorescent powder mixed in a transparent adhesive material. The reason is that a fluorescent powder will deposit in a transparent adhesive material after mixing with the transparent adhesive material, and when the mixed transparent adhesive material is injected into different LED package housings, the LEDs produced in earlier stage will have more fluorescent powder, and the LEDs produced in later stage will get less fluorescent powder. This will result in LEDs in a same batch have different light colors ranging from yellow to blue. After LEDs are packaged, there will be only one portion that meets specs can be used in commercial applications. That is, the yield rate depends on the depositing speed of the fluorescent powder in the transparent adhesive material, but the depositing speed is hard to predict.

Besides, the mixed transparent adhesive material will solidify after being injected into a package housing of an LED. As the material of the package housing is generally PPA (polyphthalamide), and the transparent adhesive material is epoxy resin or silicon resin, although both the two materials are organic materials, still, the interface between them will remain gaps, and the size of the gaps will increase after the mixed transparent adhesive material solidifies due to different thermal expansion coefficients of the two materials. As a result, the packaged LED will be hard to be airtight, and the applications of the packaged LEDs will be severely limited accordingly.

What is more, if a secondary optical structure—an optical lens, for example—is to be formed on a packaged LED to provide a light pattern required by an application, more cost will be induced and the product yield rate will be lower.

In view of the problems mentioned above, the present invention proposes an LED package structure and an LED packaging manner to conquer the mentioned disadvantages in traditional LED packaging.

### SUMMARY OF THE INVENTION

To attain the goal mentioned above, the present invention proposes a solid state lighting device, which includes a housing having a reflective cup, a solid state light source inside the housing, a transparent adhesive material for sealing the solid state light source inside the housing, and a multi-layer fluorescent structure placed on the transparent adhesive material for absorbing light from the solid state light source and then emitting light of longer wavelengths, wherein the multi-layer fluorescent structure includes a fluorescent layer or a phosphor layer attached on a first transparent adhesive layer.

In one embodiment, the multi-layer fluorescent structure further includes a second transparent adhesive layer so that the fluorescent layer or the phosphor layer is sandwiched between the first transparent adhesive layer and the second transparent adhesive layer.

In one embodiment, the solid state light source is an LED of blue light or ultraviolet light.

In one embodiment, the refractive index of the transparent adhesive material is between that of the solid state light source and that of the multi-layer fluorescent structure, and the multi-layer fluorescent structure is capable of providing an airtight sealing for the solid state lighting device.

In one embodiment, the fluorescent layer or the phosphor layer is of multi-layer to emit light of different wavelengths after absorbing light from the solid state light source. The multi-layer fluorescent structure is fixed on the transparent adhesive material by thermal curing or ultraviolet curing.

In one embodiment, the multi-layer fluorescent structure has a micro structure on a light output surface for light scattering. The light output surface is implemented by a Fresnel lens having a light converging effect or a light diverging effect.

To make it easier for our examiner to understand the objective of the invention, its structure, innovative features, and performance, we use preferred embodiments together with the accompanying drawings for the detailed description of the invention.

### BRIEF DESCRIPTION OF THE DRAWINGS

FIG. 1 illustrates a cross sectional view of a solid state lighting device according to a preferred embodiment of the present invention.

FIG. 2 illustrates a cross sectional view of a solid state lighting device having an airtight sealing arrangement according to a preferred embodiment of the present invention.

FIG. 3 illustrates a cross sectional view of a solid state lighting device having an airtight sealing arrangement according to another preferred embodiment of the present invention.

FIG. 4 illustrates a cross sectional view of a multi-layer fluorescent structure having a micro structure atop according to a preferred embodiment of the present invention.

FIG. 5 illustrates the structure of a Fresnel lens.

FIG. 6 illustrates the principle of a Fresnel lens.

FIG. 7 illustrates a flow chart for manufacturing a solid state lighting device according to a preferred embodiment of the present invention.

### DETAILED DESCRIPTION OF THE PREFERRED EMBODIMENTS

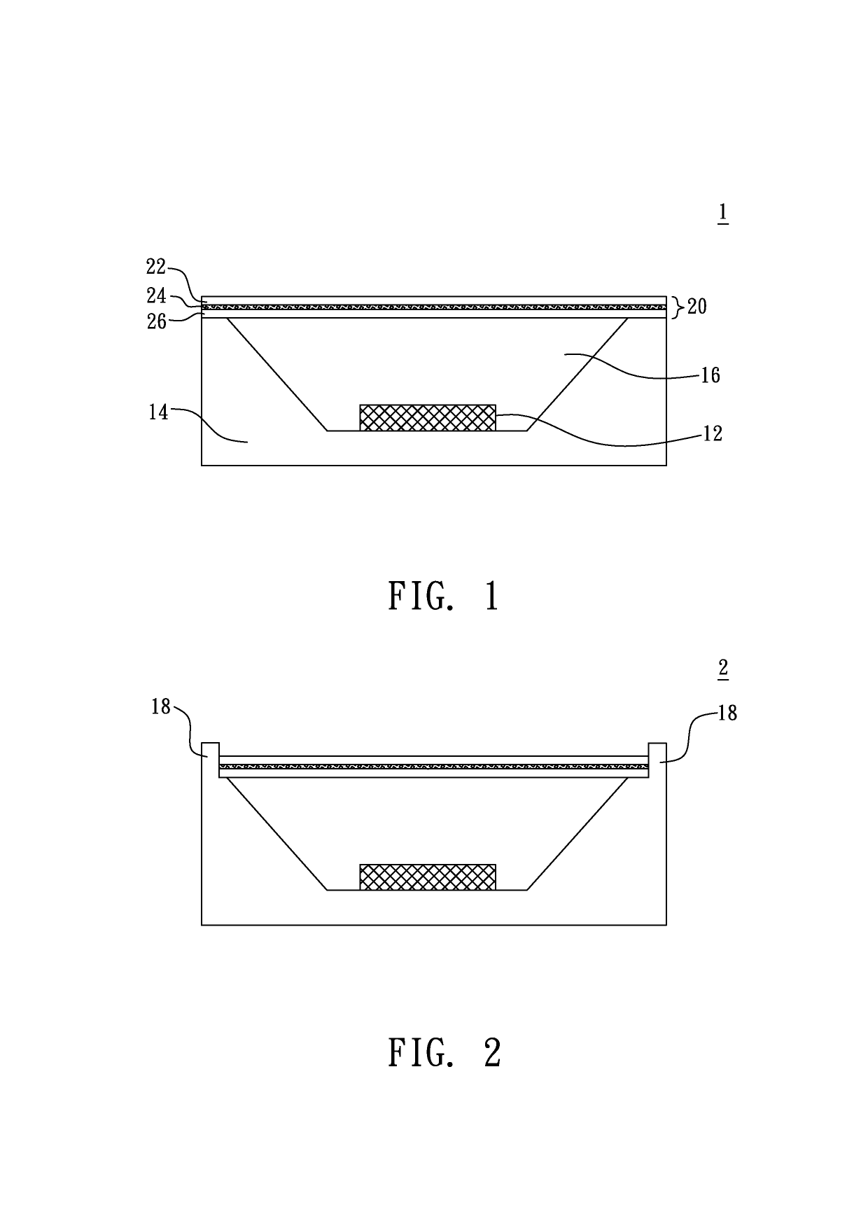

Please refer to FIG. 1, which illustrates a cross sectional view of a solid state lighting device according to a preferred embodiment of the present invention. As illustrated in FIG. 1, a solid state lighting device 1 includes a housing 14 for accommodating an LED chip 12. The package of the solid state lighting device 1 can be implemented by PLCC (plastic lead frame chip carrier) packaging, printed circuit board packaging, ceramic packaging, or silicon packaging.

The housing 14 can include a reflective cup (not shown in the figure) inside for reflecting light, but it is to be known that the reflective cup is not a necessary component in the present invention. When PLCC packaging is used, the material of the housing 14 is preferably PPA (polyphthalamide); when ceramic packaging is used, the material of the housing 14 is preferably aluminum oxide or aluminum nitride ceramics; and when silicon packaging is used, the material of the housing 14 is preferably single crystal silicon.

In this preferred embodiment, at least one LED is used as the solid state light source. The LED chip 12 can be implemented by three-five compound semiconductors, majorly gallium nitride, or two-six compound semiconductors.

In this embodiment, the at least one LED is mainly of the type of gallium nitride LED and is capable of emitting blue light or ultraviolet light with wavelengths ranging between 370 nm and 480 nm. The wavelength of the at least one LED is determined by the energy level of an active layer.

The space inside the housing 14 is filled with a transparent adhesive material 16, which can be an epoxy, a silicone, or a hybrid of both. Epoxy has better hardness though, but, due to a benzene ring it contains, it is inclined to yellow to decay the light intensity of LEDs. Silicone has inferior hardness but is not inclined to yellow. For the present, a hybrid of both mentioned materials is available in the market to provide a material having good hardness and not inclined to yellow.

Besides, the refractive index of the transparent adhesive material 16 is preferably between that of the LED chip 12 and that of a multi-layer fluorescent structure 20. In one embodiment, the transparent adhesive material 16 can even be omitted due to a fact that the solid state lighting device 1 can be sealed by the multi-layer fluorescent structure 20 at a final step.

The multi-layer fluorescent structure 20, placed on the housing 14 and the transparent adhesive material 16, has a fluorescent layer 24 sandwiched by a transparent adhesive layer 22 and a transparent adhesive layer 26.

The fluorescent layer 24 can be implemented by a phosphor material or a fluorescent material, which can be YAG (yttrium aluminum garnet), TAG (terbium aluminum garnet), silicate, organic garnet, sulfide, selenide, or nitride. The material choice of the fluorescent layer 24 is dependent on applications. For example, when the at least one LED is of blue light, the fluorescent layer 24 can be implemented by a fluorescent powder capable of generating yellow light—like YAG fluorescent powder, TAG fluorescent powder, silicate fluorescent powder, or organic garnet powder; or a fluorescent powder combination capable of generating green light and red light—for example, using both green light silicate fluorescent powder and red light sulfide or nitride fluorescent powder.

As the fluorescent layer 24 is sandwiched by the transparent adhesive layer 22 and the transparent adhesive layer 26, the width of the fluorescent layer 24 can be controlled easily. If the fluorescent layer 24 is implemented by a thicker layer of a yellow fluorescent powder to generate more yellow light, and the LED chip 12 is of blue light, then the solid state lighting device 1 will provide warm white light of lower color temperatures. On the other hand, if the fluorescent layer 24 is implemented by a thinner layer of a yellow fluorescent powder to generate less yellow light, and the LED chip 12 is of blue light, then the solid state lighting device 1 will provide cool white light of higher color temperatures. In contrast, traditional manufacturing methods mix a transparent adhesive material with a fluorescent powder first, and then inject the mixed transparent adhesive material into the housing 16. By traditional manufacturing methods, the particles of the fluorescent powder will deposit gradually, and each LED will have a different density of the fluorescent powder accordingly. As a result, the white light of the produced LEDs will have a distribution in a CIE space. In some applications, especially for the backlight of displays, the color of displayed images will be distorted if the distribution in the CIE diagram is widely dispersed. Besides, the produced white light LEDs have to be classified according to their CIE colors, and then delivered to clients according to different spec requirements. However, if the spec of some of the white LEDs does not meet any market requirement, as those LEDs cannot be reworked, they will be held in stock or sold at extremely low prices. The deposition of a fluorescent powder is hard to control, so there will be a relatively high ratio of products held in stock if a traditional manufacturing method is used to produce the white light LEDs.

Using the method of the present invention can avoid the mentioned problem caused by the deposition of a fluorescent powder. The produced white light LEDs of the present invention will have a narrow distribution in the CIE space. The requirements of clients on CIE colors can be met by adjusting the thickness of the fluorescent layer 24.

The transparent adhesive layer 22 and the transparent adhesive layer 26 can be implemented by PMMA (polymethyl methacrylate), acryl, PC (Polycarbonate), PE (polyethylene), or PVC (Polyvinylchloride). Under the transparent adhesive layer 26, a thermal curing resin or a UV curing resin can be applied to attach the multi-layer fluorescent structure 20 to the housing 14 and to the transparent adhesive material 16.

For other possible embodiments, the multi-layer fluorescent structure 20 can include only the transparent adhesive layer 26 and the fluorescent layer 24, or only the transparent adhesive layer 22 and the fluorescent layer 24, as long as the fluorescent layer 24 has a transparent adhesive layer to attach to. Besides, a diffuser can be added in the transparent adhesive layer 22 or 26.

FIG. 2 illustrates a cross sectional view of a solid state lighting device 2 having an airtight sealing arrangement according to a preferred embodiment of the present invention. After the multi-layer fluorescent structure 20 is attached, a fixture 18 can be formed around the surface of the housing 14 in airtight way to make the solid state lighting device 2 applicable in outdoor environments.

The fixture 18, of which the material can be Polyphthalamide or ceramics, is attached to the housing 14 by thermal curing under a high pressure.

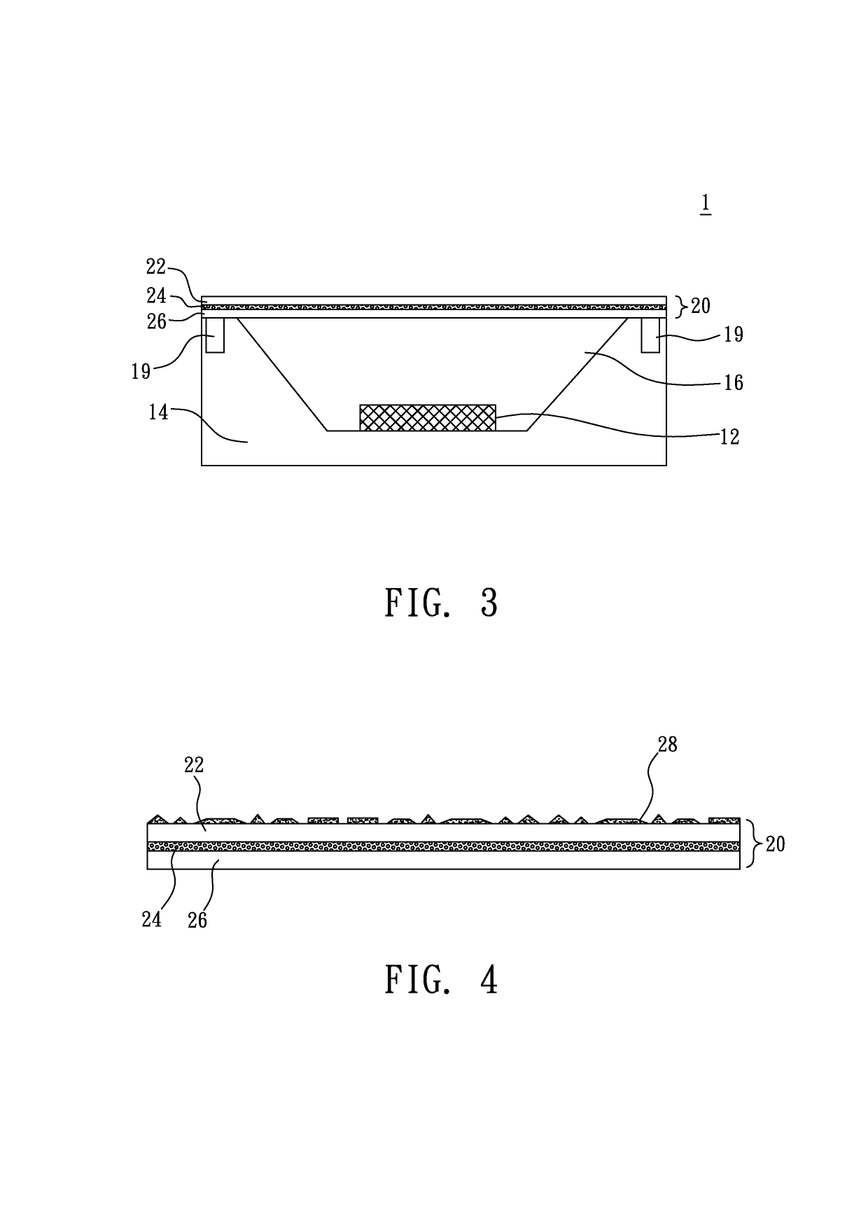

Please refer to FIG. 3, two ditches 19 can be formed at the side walls of the housing 14, and an adhesive material can then be filled into the ditches 19. The multi-layer fluorescent structure 20 can then be attached to the solid state lighting device 1 in an airtight way. In one embodiment, two ends of the multi-layer fluorescent structure 20 can stretch into the ditches 19 to make the solid state lighting device 1 sealed in a more airtight way.

The adhesive material in the ditch 19 can be same as or different from the transparent adhesive material 16. For example, both can use epoxy or silicone. As the adhesive material in the ditches 19 has no LED light passing through, it can be opaque.

In addition, as illustrated in FIG. 4, a micro structure 28 can be formed on the top surface of the multi-layer fluorescent structure 20—to be specific, on the top surface or light output surface of the transparent adhesive layer 22. In recent researches, it is found that adding a micro structure on an LED light output surface to increase the roughness thereof can improve the light output efficiency. Besides, as the microstructure 28 is close to the fluorescent layer 24, it can also help to improve the light mixing effect.

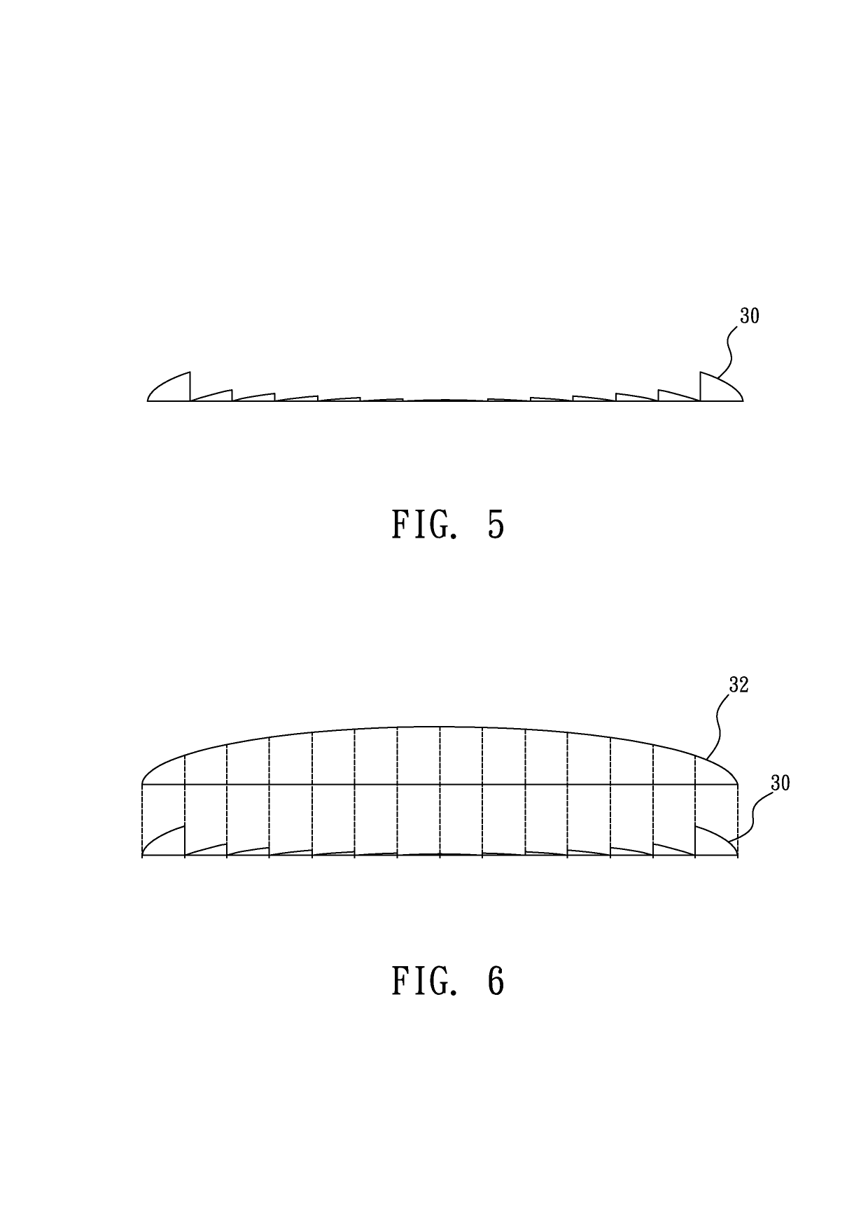

Beside the microstructure 28, a secondary optical structure can also be formed on the top surface of the transparent adhesive layer 22. If light converging is required, a Fresnel lens 30, as illustrated in FIG. 5, can be formed on the top surface of the transparent adhesive layer 22. The principle of the Fresnel lens 30 is illustrated in FIG. 6. As illustrated in FIG. 6, a lens 32 is divided into multiple portions, and the curved surfaces of the multiple portions are shifted downward to the bottom to substantially reduce the thickness of the Fresnel lens 30.

As can be seen in FIG. 5 and FIG. 6, the Fresnel lens 30 is implemented according to a convex lens—the lens 32—to provide a light converging effect. However, it is to be known that the thickness of any kind of optical lens can be reduced in this way.

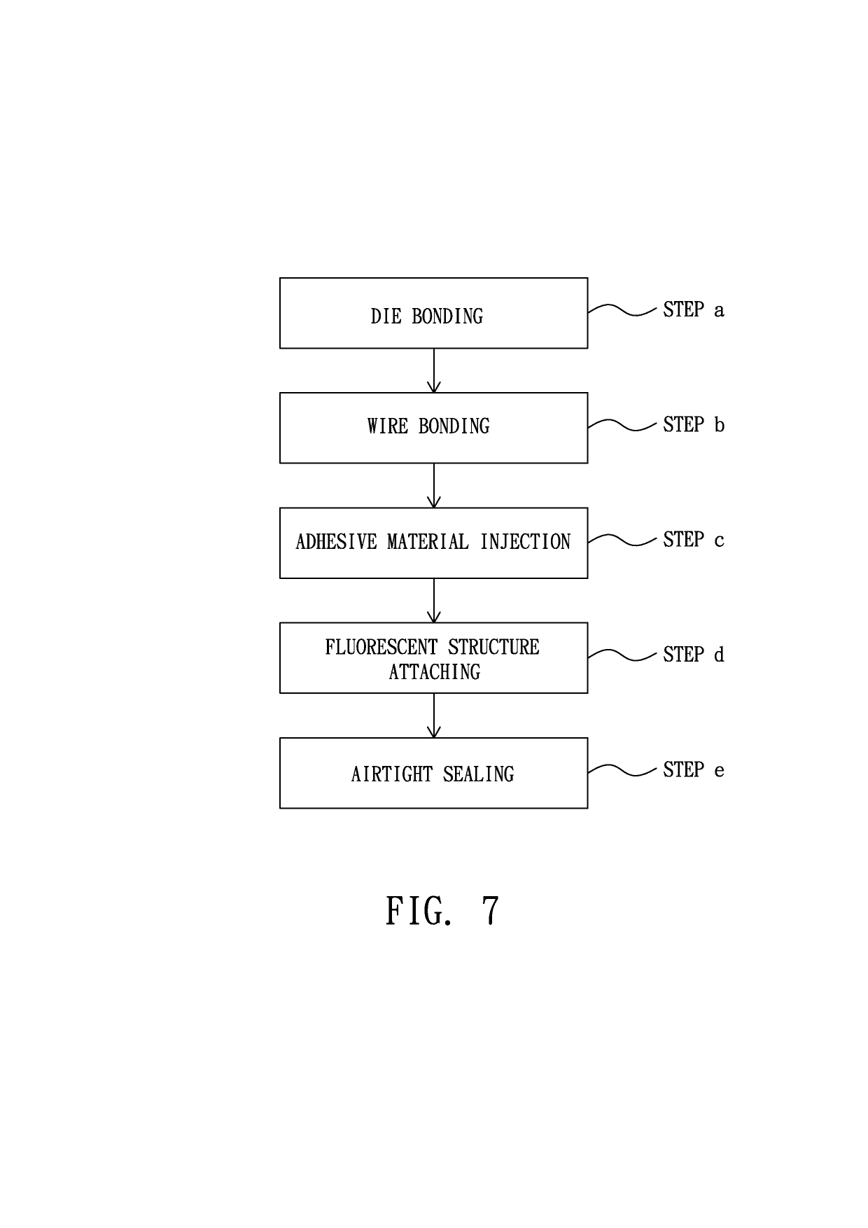

The manufacturing process of the present invention's solid state lighting device is illustrated in FIG. 7.

First, a die bonding step (step a) and a wire bonding step (step b) are performed. If flip chip packaging technology is adopted, only the die bonding step is needed.

Second, perform an adhesive material injection step (step c). As the adhesive material involved in this step is a transparent material without a fluorescent powder, there will be no fluorescent powder deposition problem in the present invention. Besides, step c is an optional step, that is, the adhesive material injection step can be omitted.

Third, a fluorescent structure attaching step (step d) is performed to attach the fluorescent structure onto a housing and a transparent material. This step can utilize a thermal curing procedure or a UV curing procedure to fix the fluorescent structure. Finally, an airtight sealing step (step e)—an optional step—can be performed if the solid state lighting device is to be used outdoors.

Although the specification of the foregoing embodiments of the present invention focuses on solid state lighting devices, the structures thereof can also be applied to solid state lighting systems. For example, by using chip-on-board technology, the LED chip 12 in FIG. 1 can be viewed as a chip including multiple LEDs, the solid state lighting device 1 can be viewed as a solid state lighting system, and the housing 14 can be a circuit board plus a stiff shell—for example, a printed circuit board or a ceramic board plus a metallic shell—to save the packaging process of LEDs. To implement a solid state lighting system, some manufacturing steps are needed. First, suitable ones of manufactured LED chips are selected according to a sorting process on light wavelength, operation voltage, and light intensity. Second, a bonding process is performed on the suitable LED chips. Third, a sealing and packaging process is performed to complete the solid state lighting system. The solid state lighting system can be used as the back light of a liquid crystal display, or used for indoor or outdoor illumination.

The advantages of the present invention are as follows. First, the deposition problem of a fluorescent powder in a transparent adhesive material is solved, and the CIE color distribution of produced white light LEDs can therefore be prevented from spreading. That is, as the fluorescent powder density of the fluorescent layer is easy to control and the fluorescent layer does not have the fluorescent powder deposition problem, therefore, white light LEDs having a narrow CIE color distribution can be provided. Second, the manufacturing process of the present invention has superior stability. Finally, as the present invention can provide superior airtight sealing and a secondary optical structure easily without adding other elements or materials, the manufacturing process of the present invention is more simplified and convenient than that of prior art devices.

While the invention has been described by way of example and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance than the conventional structure and further complies with the patent application requirements and is submitted to the Patent and Trademark Office for review and granting of the commensurate patent rights.

What is claimed is:

1. A solid state lighting device, comprising:
a housing, having a reflective cup inside;
a solid state light source, placed inside said housing; and
a multi-layer fluorescent structure, placed on said housing and having a fluorescent layer or a phosphor layer attached with a first transparent adhesive layer, so as to absorb light beams from said solid state light source and then emit light of longer wavelengths.

2. The solid state lighting device as claim 1, further comprising a transparent adhesive material to seal said solid state light source in said housing.

3. The solid state lighting device as claim 2, wherein said multi-layer fluorescent structure further comprises a second transparent adhesive layer so that said fluorescent layer or said phosphor layer is sandwiched by said first transparent adhesive layer and said second transparent adhesive layer.

4. The solid state lighting device as claim 1, wherein said multi-layer fluorescent structure has a micro structure on a light output surface for light scattering.

5. The solid state lighting device as claim 3, wherein said multi-layer fluorescent structure has a micro structure on a light output surface for light scattering.

6. The solid state lighting device as claim 1, wherein said multi-layer fluorescent structure has a Fresnel lens on a light output surface for light converging or light diverging.

7. The solid state lighting device as claim 3, wherein said multi-layer fluorescent structure has a Fresnel lens on a light output surface for light converging or light diverging.

8. The solid state lighting device as claim 1, wherein said fluorescent layer or said phosphor layer in said multi-layer fluorescent structure is of multi layers, and is capable of emitting light of different wavelengths after absorbing light beams from said solid state light source.

9. The solid state lighting device as claim 3, wherein said fluorescent layer or said phosphor layer in said multi-layer fluorescent structure is of multi layers, and is capable of emitting light of different wavelengths after absorbing light beams from said solid state light source.

10. The solid state lighting device as claim 1, wherein said multi-layer fluorescent structure is attached onto said transparent adhesive material by thermal curing.

11. The solid state lighting device as claim 3, wherein said multi-layer fluorescent structure is attached onto said transparent adhesive material by thermal curing.

12. The solid state lighting device as claim 1, wherein said multi-layer fluorescent structure is capable of providing an airtight sealing for said solid state light source.

13. The solid state lighting device as claim 3, wherein said multi-layer fluorescent structure is capable of providing an airtight sealing for said solid state light source.

14. The solid state lighting device as claim 2, wherein said transparent adhesive material has a refractive index between a refractive index of said solid state light source and a refractive index of said multi-layer fluorescent structure.

15. The solid state lighting device as claim 1, wherein said solid state light source includes an LED.

16. The solid state lighting device as claim 3, wherein said solid state light source includes an LED.
